(19) United States
(12) Patent Application Publication
(10) Pub. No.: US 2013/0315728 A1
(43) Pub. Date: Nov. 28, 2013

(54) FIXING DEVICE FOR FAN

(71) Applicants: HAI-QING ZHOU, Shenzhen City (CN); YI-XIN TU, Shenzhen City (CN)

(72) Inventors: HAI-QING ZHOU, Shenzhen City (CN); YI-XIN TU, Shenzhen City (CN)

(73) Assignees: HON HAI PRECISION INDUSTRY CO., LTD., Tu-Cheng (TW); HONG FU JIN PRECISION INDUSTRY (ShenZhen) Co., LTD., Shenzhen City (CN)

(21) Appl. No.: 13/525,389

(22) Filed: Jun. 18, 2012

(30) Foreign Application Priority Data
May 28, 2012 (CN) 201210168257.9

(51) Int. Cl. F04D 29/60; F16M 13/02; H05K 7/20; F16M 13/00

(52) U.S. Cl. 415/213.1; 248/674

(57) ABSTRACT

A fixing device includes a support fixed in a chassis, and a bracket installing a fan. The support includes a mounting plate. The mounting plate defines a vent area and a number of latching holes located around the vent area. The bracket includes a number of pins respectively latched into the latching holes of the support and a positioning portion. A tab protrudes from the support, to engage with the positioning portion of the bracket. An elastic portion extends down from the bracket to resiliently abut against the chassis.

### BACKGROUND

1. Technical Field

The present disclosure relates to fixing devices, and particularly to a fixing device for a fan.

2. Description of Related Art

Fans are widely used in computer systems for dissipating heat. One or more fans are secured by screws or the like to an enclosure of the computer system. The fans are used for producing airflow to dissipate heat from electrical components within the enclosure, thus keeping the components operating within a desired temperature range. However, as computer systems become smaller in size, the components are more tightly arranged within the enclosure of the computer system. When the fans are secured to or removed from the enclosure, the use of a screwdriver for screwing or unscrewing the screws may cause damage to the components, as there is not enough space for the screwdriver within the enclosure of the computer system. In addition, the installation or removal of the screws is time consuming and troublesome.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the views.

FIG. 1 is an exploded, isometric view of an exemplary embodiment of a fixing device, together with a part of a chassis and a fan, wherein the fixing device includes a bracket.

FIG. 2 is similar to FIG. 2, but viewed from another perspective.

FIG. 3 is an enlarged view of the bracket of FIG. 2.

FIG. 4 is an assembled view of FIG. 2.

FIG. 5 is an assembled view of FIG. 1, but partially cutaway.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references can mean “at least one.”

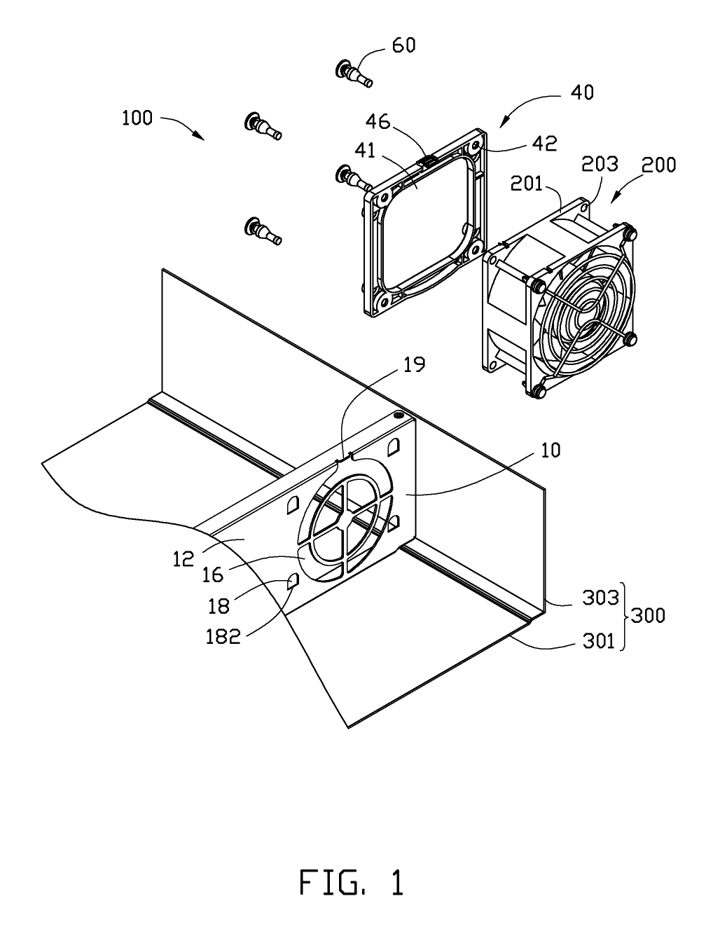

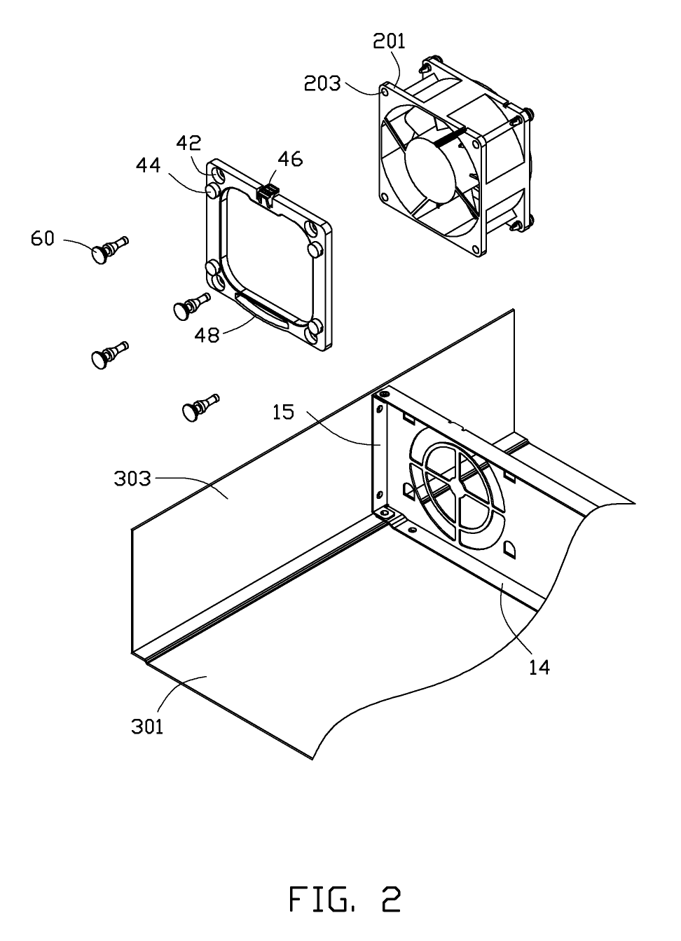

Referring to FIGS. 1 and 2, aspects of an exemplary embodiment of a fixing device 100 are shown. The fixing device 100 is used for fixing one or more fans 200 in a chassis 300 of an electronic device. Each fan 200 includes two opposite side plates 201. Four corners of each side plate 201 define four fixing holes 203. The chassis 300 includes a bottom wall 301 and two sidewalls 303 perpendicularly extending up from the bottom wall 301. The fixing device 100 includes a support 10 and a bracket 40.

The support 10 includes a rectangular mounting plate 12, a side plate 14 perpendicularly extending out from a bottom side of the mounting plate 12, and two end plates 15 perpendicularly extending out from two opposite ends of the mounting plate 12. The side plate 14 and the end plates 15 are respectively secured to the bottom wall 301 and the sidewalls 303 of the chassis 300. A plurality of vent areas 16 is formed on the mounting plate 12, arranged along the lengthwise direction of the mounting plate 12. Each vent area 16 defines a plurality of vents. The mounting plate 12 defines four latching holes 18, around each vent area 16. Each latching hole 18 is bounded by an arced top side and a straight bottom side 182. A tab 19 perpendicularly extends from a top of each vent area 16 of the mounting plate 12, away from the side plate 14.

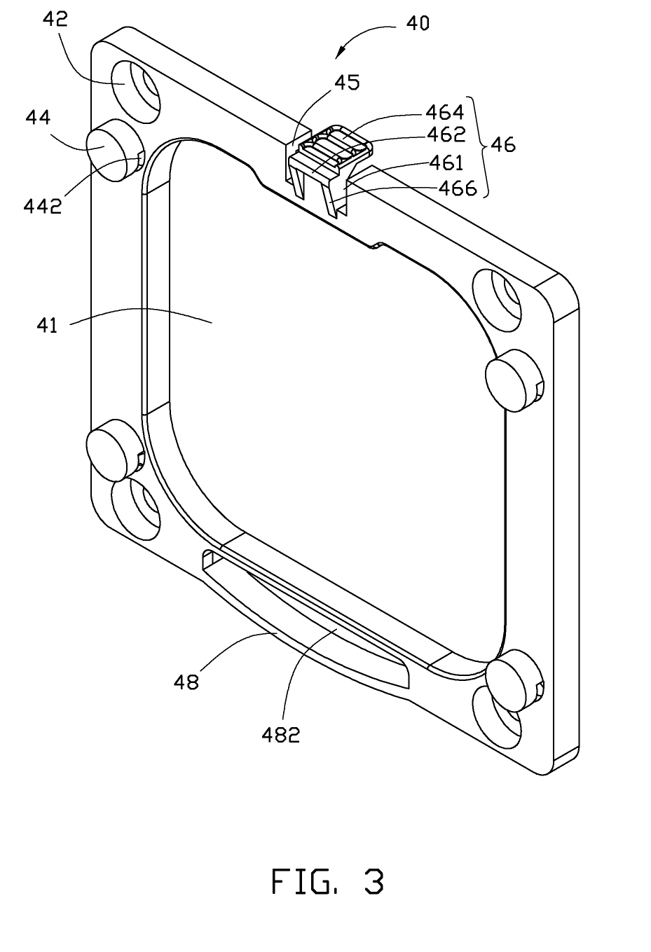

Referring to FIG. 3, the bracket 40 is substantially rectangular, and defines an opening 41 in a middle of the bracket 40 and four through holes in four corners of the bracket 40. Two cylindrical pins 44 protrude from each of opposite sides of the bracket 40. A bottom of each pin 44 defines a latching slot 442 adjacent to the bracket 40. A cutout 45 is defined in a top side of the bracket 40. A positioning portion 46 extends up from a bottom wall of the cutout 45. The positioning portion 46 includes an elastic extending plate 461 extending up from the bottom wall of the cutout 45, a positioning block 462 extending from a distal end of the extending plate 461 along an extending direction of the pins 44, an operation plate 464 extending from the distal end of the extending plate 461 away from the positioning block 462, and a guiding block 466 protruding from the extending plate 461 and connected to the positioning block 462. A surface of the guiding block 466 opposite to the extending plate 461 is slanted. An arc-shaped elastic portion 48 extends down from a bottom of the bracket 40, and defines an arc-shaped slot 482.

In the embodiment, the bracket 40 is made of elastic material, such as plastic.

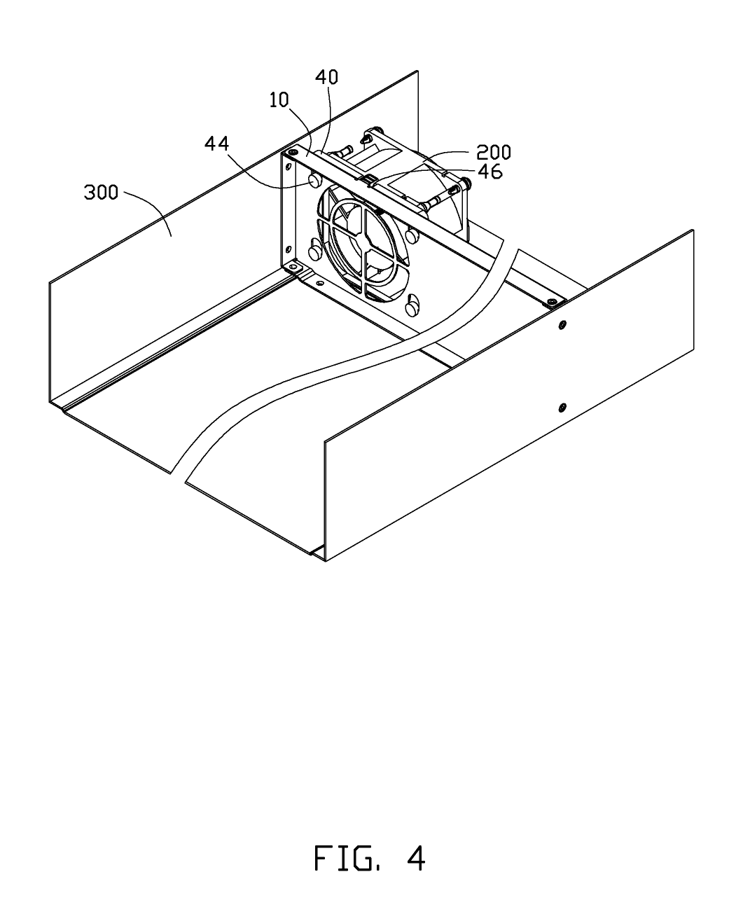

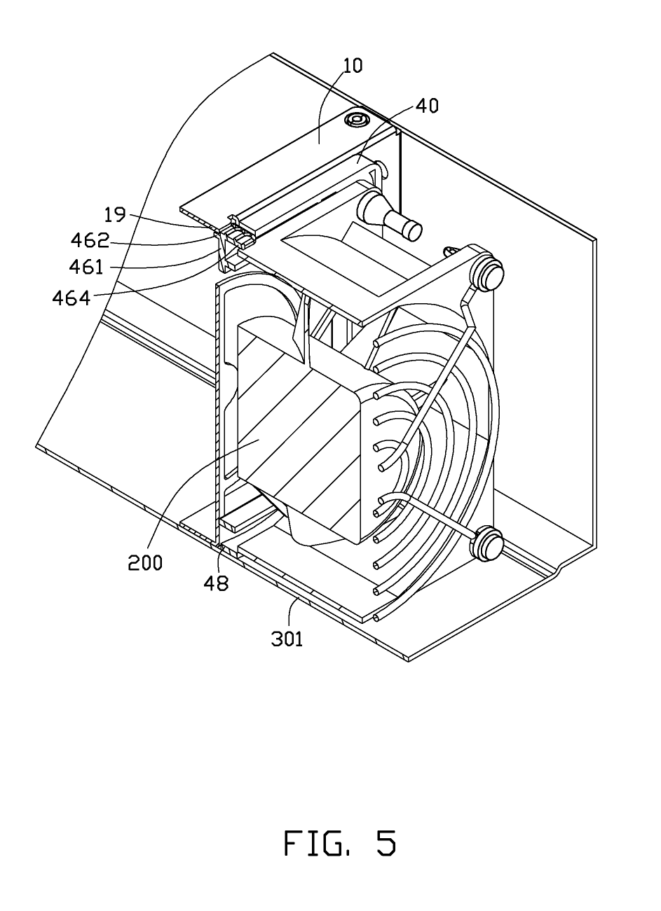

Referring to FIGS. 4-5, in assembly, the bracket 40 is attached to one of the side plates 201 of the fan 200, with the pins 44 facing away from the fan 200. Four fastening members 60 respectively extend through the through holes 42 of the bracket 40, to be latched into the corresponding fixing holes 203 of the fan 200. The pins 44 of the bracket 40 are respectively inserted into the latching holes 18 of the support 10, until the latching slot 442 of each pin 44 aligns with the bottom side 182 of the corresponding latching hole 18. The bracket 40 is pressed down, to allow the bottom sides 182 of the latching holes 18 to be inserted into the latching slots 442, and the elastic portion 48 is resiliently abutted against the bottom wall 301 of the chassis 300. The guiding block 466 movably abuts against the tab 19 of the support 10, to deform the extending plate 461, until the positioning block 462 is moved below the tab 19. The extending plate 461 is restored to abut against a top of the positioning block 462. Thereby, a combination of the bracket 40 and the fan 200 is mounted to the support 10. Because the elastic portion 48 of the bracket 40 is resiliently abutted against the bottom wall 301 of the chassis 300, when the fan 200 is shaken, the elastic portion 48 can absorb the energy of the vibrations.

In disassembly, the operation plate 464 is operated to disengage the positioning block 462 from the tab 19. The pins 44 are detached from the latching holes 18 by moving the bracket 40 up. The combination of the fan 200 and the bracket 40 then can be easily removed from the support 10.

While the disclosure describes examples and embodiments, it is to be understood that the disclosure is not limited thereto. To the contrary, the disclosure is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A fan bracket, comprising:
a bracket body to be attached to a side of a fan, and defining an opening in a center thereof to align with the fan, a bottom side of the bracket body forming an elastic portion protruding down;
a pin extending from a side of the bracket opposite to the fan; and
a positioning portion extending from a top side of the bracket body opposite to the elastic portion.

2. The fan bracket of claim 1, wherein the bracket body further defines a cutout in the top side of the bracket body, the positioning portion extending up from a bottom wall bounding the cutout.

3. The fan bracket of claim 2, wherein the positioning portion comprises a cantilevered extending plate extending up from the bottom wall bounding the cutout, and a positioning block extending from a distal end of the extending plate away from the fan.

4. The fan bracket of claim 3, wherein an operation plate extends from the distal end of the extending plate away from the positioning block.

5. The fan bracket of claim 1, wherein the pin defines a latching slot in a bottom and adjacent to the bracket body.

6. The fan bracket of claim 1, wherein the bottom side of the bracket body arced down, and defines an arc-shaped slot.

7. The fan bracket of claim 1, wherein the bracket body further defines four through holes in four corners of the bracket body to fix the fan.

8. A fixing device for a fan, comprising:
a support mounted in a chassis, and comprising a mounting plate and a tab extending out from the mounting plate, the mounting plate defining a vent area and a plurality of latching holes located around the vent area; and
a bracket installing the fan, and comprising a plurality of pins respectively latched into the latching holes of the support, a positioning portion protruding from the bracket to engage with the tab of the support, and an elastic portion extending down from the bracket to resiliently abut against the chassis.

9. The fixing device of claim 8, wherein the mounting plate is rectangular, a vent area is defined in the mounting plate, each latching hole is adjacent to a corresponding corner of the vent area.

10. The fixing device of claim 9, wherein a bottom of each pin defines a latching slot, each latching hole is bounded by a straight bottom side latched into the corresponding latching slot.

11. The fixing device of claim 8, wherein the tab extends out from a top of the vent area of the mounting plate, and the positioning portion extends up from a top side of the bracket.

12. The fixing device of claim 11, wherein the positioning portion comprises an extending plate extending up from the bracket, a positioning block extending out from a distal end of the extending plate along an extending direction of the pins, and a guiding block connected between the extending plate and the positioning block, the guiding block movably abuts against the tab of the support, to deform the extending plate until the positioning block moves below the tab to abut against a bottom of the tab.

13. The fixing device of claim 12, wherein the positioning portion further comprises an operation plate extending from the distal end of the extending plate away from the positioning block.

14. The fixing device of claim 8, wherein the elastic portion is substantially arc-shaped, and extends down from a bottom side of the bracket.

15. The fixing device of claim 14, wherein the elastic portion defines a slot.

16. The fixing device of claim 8, wherein the bracket is made of elastic material.

17. A computer enclosure, comprising:
a chassis comprising a bottom wall, and a support extending up from the bottom wall, the support defining a vent area, and a latching hole adjacent to the vent area, a tab extending from the support above the vent area;
a fan; and
a bracket comprising a bracket body fixed to a side of the fan, a pin extending from a surface of the bracket body opposite to the fan to engage in the latching hole, a positioning portion extending from a top side of the bracket body to engage with the tab, and an elastic portion extending down from a bottom side of the bracket body opposite to the top side to resiliently abut against the bottom wall, thereby the fan aligning with the vent area.

18. The computer enclosure of claim 17, wherein the bracket body also defines a cutout in the top side of the bracket body, the positioning portion comprises a cantilevered extending plate extending up from a bottom wall bounding the cutout, a positioning block extending from a distal end of the extending plate away from the fan, and an operation plate extending from the distal end of the extending plate away from the positioning block.

19. The computer enclosure of claim 17, wherein the pin defines a latching slot in a bottom and adjacent to the bracket body to receive a bottom wall bounding the latching hole of the support.

20. The computer enclosure of claim 17, wherein the bottom side of the bracket body is arced down, and defines a slot.
